(19) United States
(12) Patent Application Publication
(10) Pub. No.: US 2024/0414858 A1
(43) Pub. Date: Dec. 12, 2024

(54) CELL BOX

(71) Applicant: Sharp Display Technology Corporation, Kameyama City (JP)

(72) Inventor: Kohji OKUYAMA, Kameyama City (JP)

(21) Appl. No.: 18/642,609

(22) Filed: Apr. 22, 2024

(30) Foreign Application Priority Data
Jun. 6, 2023 (JP) 2023-093397

(51) Int. Cl. H05K 5/02; H05K 5/00

(52) U.S. Cl. CPC H05K 5/0217; H05K 5/0018

(57) ABSTRACT

A cell box includes a bottom portion defining a bottom surface of a housing space in which a display panel and a protective sheet are housed in an overlapping manner, and a side wall portion defining a side surface of the housing space. The housing space includes a first space in which the display panel is disposed and a second space in which the display panel is not disposed and a part of the protective sheet is disposed, one or more protruding portions protruding into the second space are provided in the bottom portion, the protruding portions include a first portion extending in a normal direction of the bottom surface and a second portion more distant from the bottom surface than the first portion is, and the second portion includes an overhanging portion more overhanging than the first portion when viewed from the normal direction of the bottom surface.

### CROSS-REFERENCE TO RELATED APPLICATIONS

This application claims the benefit of priority to Japanese Patent Application Number 2023-093397 filed on Jun. 6, 2023. The entire contents of the above-identified application are hereby incorporated by reference.

### BACKGROUND

### Technical Field

The disclosure relates to a cell box including a housing space in which a display panel and a protective sheet are housed in an overlapping manner.

For example, JP 2009-18898 A, JP 2011-42419 A, and JP 2007-161354 A describe a protective sheet removing device and an unpacking system that can be used when a protective sheet is removed from a cell box including a housing space for housing a display panel and a protective sheet in an overlapping manner.

### SUMMARY

However, the protective sheet removing device and the unpacking system described in JP 2009-18898 A, JP 2011-42419 A, and JP 2007-161354 A need to be separately installed by a user who will remove the display panel from the cell box, which imposes a heavy burden in terms of cost.

An object of one aspect of the disclosure is to prevent the protective sheet from being lifted up along with a display panel when a display panel is removed from a cell box.

To solve the above-described problem, a cell box according to the disclosure includes a bottom portion defining a bottom surface of a housing space in which a display panel and a protective sheet are housed in an overlapping manner, and a side wall portion defining a side surface of the housing space, in which the housing space includes a first space in which the display panel is disposed and a second space in which the display panel is not disposed and a part of the protective sheet is disposed, one or more protruding portions protruding into the second space are provided in the bottom portion, the one or more protruding portions each include a first portion extending in a normal direction of the bottom surface and a second portion more distant from the bottom surface than the first portion is, and the second portion includes an overhanging portion more overhanging than the first portion when viewed from the normal direction of the bottom surface.

According to one aspect of the disclosure, a protective sheet can be prevented from being lifted up along with a display panel when the display panel is removed from a cell box.

### BRIEF DESCRIPTION OF DRAWINGS

The disclosure will be described with reference to the accompanying drawings, wherein like numbers reference like elements.

FIG. 1 is a plan view illustrating a schematic configuration of a cell box according to a first embodiment.

FIG. 2 is a plan view illustrating an example of a protective sheet housed in a housing space of the cell box according to the first embodiment.

FIG. 3 is a perspective view illustrating a schematic configuration of the cell box according to the first embodiment.

FIG. 4 is a perspective view of a state in which a display panel and the protective sheet are housed in the housing space of the cell box according to the first embodiment.

FIG. 5 is a cross-sectional view taken along line A-A′ of FIG. 4, illustrating a state in which the display panel and the protective sheet are housed in the housing space of the cell box according to the first embodiment.

FIG. 6 is an enlarged view of a protruding portion provided in a bottom portion defining the bottom surface of the housing space of the cell box according to the first embodiment.

FIG. 7 is a diagram illustrating an example of a case in which the display panel is removed from the housing space of the cell box according to the first embodiment by using a general-purpose display panel removal device including a suction portion.

FIG. 8 is a diagram illustrating an example of a case in which the protective sheet is removed from the housing space of the cell box according to the first embodiment by using the general-purpose display panel removal device including a suction portion.

FIG. 9 is a plan view illustrating a schematic configuration of a cell box according to a second embodiment.

FIG. 10 is a plan view illustrating an example of a protective sheet housed in a housing space of the cell box according to the second embodiment.

FIG. 11 is a perspective view illustrating a schematic configuration of the cell box according to the second embodiment.

FIG. 12 is a perspective view of a state in which a display panel and the protective sheet are housed in the housing space of the cell box according to the second embodiment.

FIG. 13 is a cross-sectional view taken along line B-B′ of FIG. 12, illustrating a state in which the display panel and the protective sheet are housed in the housing space of the cell box according to the second embodiment.

FIG. 14 is a cross-sectional view taken along line C-C′ of FIG. 12, illustrating a state in which the display panel and the protective sheet are housed in the housing space of the cell box according to the second embodiment.

FIG. 15A is a plan view illustrating a schematic configuration of a first modification of the cell box according to the second embodiment.

FIG. 15B is a plan view illustrating a schematic configuration of a second modification of the cell box according to the second embodiment.

FIG. 15C is a plan view illustrating a schematic configuration of a third modification of the cell box according to the second embodiment.

FIG. 15D is a plan view illustrating a schematic configuration of a fourth modification of the cell box according to the second embodiment.

FIG. 15E is a plan view illustrating a schematic configuration of a fifth modification of the cell box according to the second embodiment.

FIG. 16A is a plan view illustrating a schematic configuration of a sixth modification of the cell box according to the second embodiment.

FIG. 16B is a plan view illustrating a schematic configuration of a seventh modification of the cell box according to the second embodiment.

FIG. 16C is a plan view illustrating a schematic configuration of an eighth modification of the cell box according to the second embodiment.

FIG. 16D is a plan view illustrating a schematic configuration of a ninth modification of the cell box according to the second embodiment.

FIG. 16E is a plan view illustrating a schematic configuration of a tenth modification of the cell box according to the second embodiment.

FIG. 17A is a plan view illustrating a schematic configuration of a cell box according to a third embodiment.

FIG. 17B is a plan view illustrating a schematic configuration of a first modification of the cell box according to the third embodiment.

FIG. 17C is a plan view illustrating a schematic configuration of a second modification of the cell box according to the third embodiment.

FIG. 17D is a plan view illustrating a schematic configuration of a third modification of the cell box according to the third embodiment.

FIG. 17E is a plan view illustrating a schematic configuration of a fourth modification of the cell box according to the third embodiment.

FIG. 17F is a plan view illustrating a schematic configuration of a fifth modification of the cell box according to the third embodiment.

FIG. 18 is a view illustrating another example of the protruding portion that can be provided in the bottom portion defining the bottom surface of the housing space of the cell box according to the first embodiment.

FIG. 19 is an enlarged view of a protruding portion provided in a bottom portion defining the bottom surface of the housing space of the cell box according to the second embodiment.

FIG. 20 is a view illustrating another example of the protruding portion that can be provided in the bottom portion defining the bottom surface of the housing space of the cell box according to the second embodiment.

FIG. 21 is a view for explaining a problem that occurs when a display panel is removed from a housing space of a known cell box by using the general-purpose display panel removal device including a suction portion.

### DESCRIPTION OF EMBODIMENTS

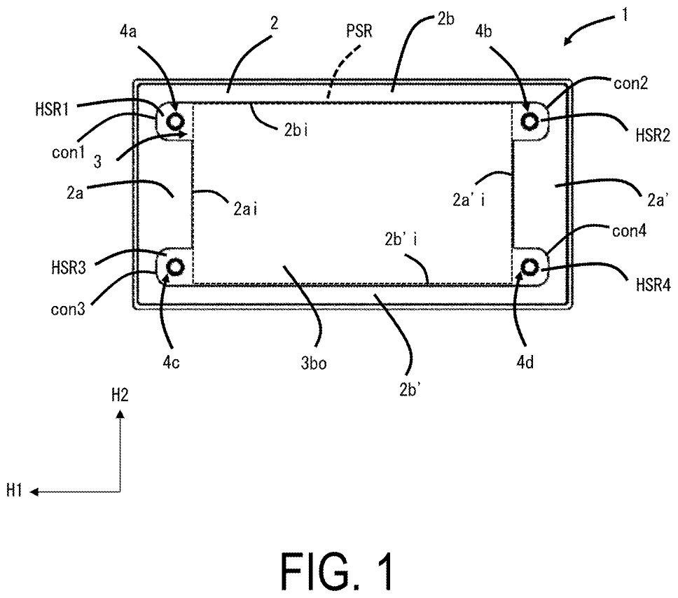

Embodiments of the disclosure will be described with reference to FIG. 1 to FIG. 21 as follows. Hereinafter, for convenience of description, configurations having the same functions as those described in a specific embodiment are denoted by the same reference signs, and descriptions thereof will be omitted.

### First Embodiment

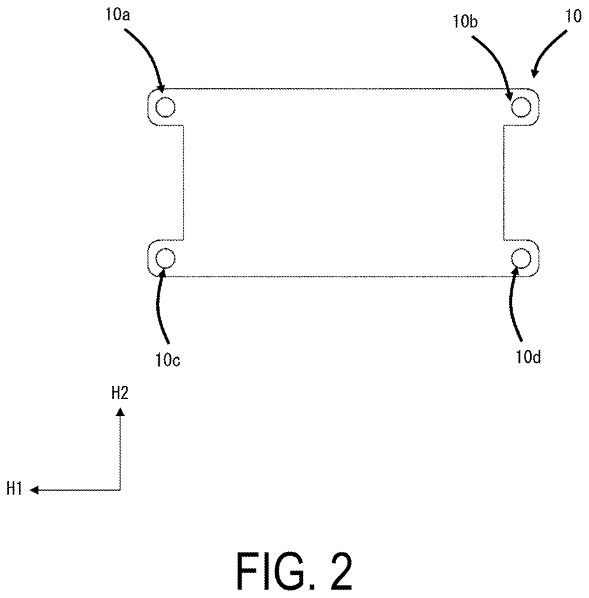

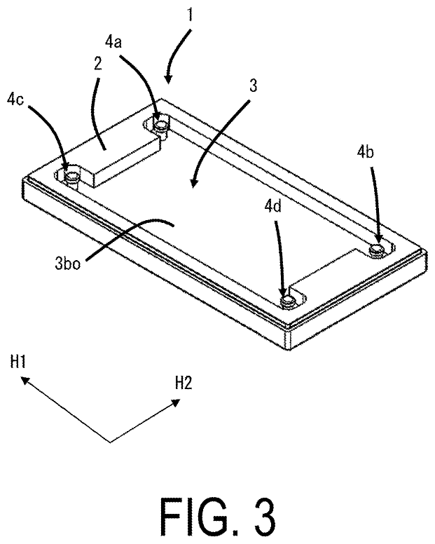

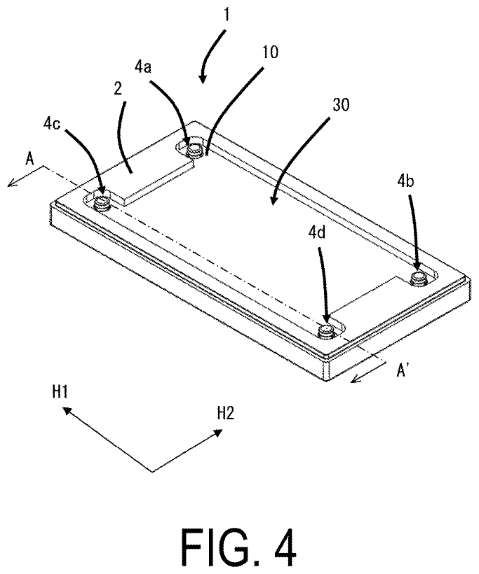

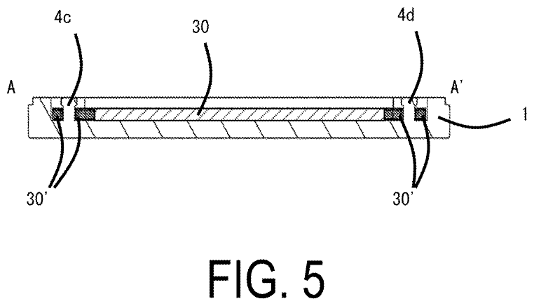

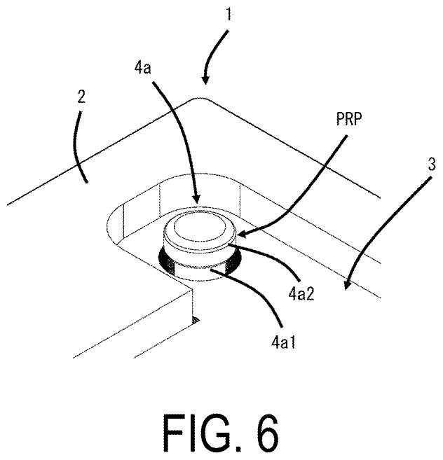

FIG. 1 is a plan view illustrating a schematic configuration of a cell box 1 according to a first embodiment. FIG. 2 is a plan view illustrating an example of a protective sheet 10 housed in a housing space 3 of the cell box 1 according to the first embodiment. FIG. 3 is a perspective view illustrating a schematic configuration of the cell box 1 according to the first embodiment. FIG. 4 is a perspective view of a state in which a display panel 20 and the protective sheet 10 are housed in the housing space 3 of the cell box 1 according to the first embodiment. FIG. 5 is a cross-sectional view taken along line A-A′ of FIG. 4, illustrating a state in which the display panel 20 and the protective sheet 10 are housed in the housing space 3 of the cell box 1 according to the first embodiment. FIG. 6 is an enlarged view of a protruding portion 4a provided in a bottom portion 3bo defining the bottom surface of the housing space 3 of the cell box 1 according to the first embodiment.

As illustrated in FIGS. 1 and 3, the cell box 1 includes the bottom portion 3bo defining the bottom surface of the housing space 3 in which the display panel 20 and the protective sheet 10 are housed in an overlapping manner, and a side wall portion 2 defining side surfaces of the housing space 3. The housing space 3 includes a first space PSR in which the display panel 20 can be disposed and second spaces HSR1, HSR2, HSR3, and HSR4 in which the display panel 20 is not disposed and a part of the protective sheet 10 can be disposed. Although a case in which the bottom portion 3bo includes protruding portions each protruding to the four separate second spaces HSR1, HSR2, HSR3, and HSR4 in a one-to-one manner and a total of four protruding portions 4a, 4b, 4c, and 4d are provided is described as an example in the present embodiment, the disclosure is not limited thereto. For example, when the housing space 3 includes only one second space, the bottom portion 3bo may be provided with one protruding portion protruding into the one second space, and when the housing space 3 includes N (N is a natural number) separate second spaces, the bottom portion 3bo may be provided with protruding portions each protruding into the N separate second spaces in a one-to-one manner, so that a total of N of the protruding portions may be provided. In addition, although a case in which the number of separate second spaces is equal to the number of protruding portions is described as an example in the present embodiment, the disclosure is not limited thereto, and a plurality of protruding portions protruding into one second space may be provided, and the protruding portions may not be provided in some of the plurality of second spaces.

As illustrated in FIG. 6, the protruding portion 4a includes a first portion 4a1 extending in the normal direction of the bottom surface of the housing space 3 (i.e., the upper surface of the bottom portion 3bo facing the housing space 3) and a second portion 4a2 more distant from the bottom surface than the first portion 4al is, and the second portion 4a2 includes an overhanging portion PRP more overhanging than the first portion 4al when viewed from the normal direction of the bottom surface. Note that the first portion 4al and the second portion 4a2 are integrally formed. Although, among the four protruding portions 4a, 4b, 4c, and 4d, only the protruding portion 4a is illustrated in FIG. 6 as an example, the other three protruding portions 4b, 4c, and 4d also include a first portion extending in the normal direction of the bottom surface and a second portion more distant from the bottom surface than the first portion is, and the second portion includes an overhanging portion more overhanging than the first portion when viewed from the normal direction of the bottom surface.

Although a case in which each of the four protruding portions 4a, 4b, 4c, and 4d is provided in the bottom portion 3bo by bonding and fixing the lower surfaces of the first portions to the bottom portion 3bo defining the bottom surface of the housing space 3 using an adhesive will be described as an example in the present embodiment, the disclosure is not limited thereto. As long as each of the four protruding portions 4a, 4b, 4c, and 4d can be fixed to the bottom portion 3bo, for example, each of the four protruding portions 4a, 4b, 4c, and 4d may be inserted into the bottom portion 3bo, or alternatively, each of the four protruding portions 4a, 4b, 4c, and 4d may be fixed to the bottom portion 3bo using another fastening member. Furthermore, in a case in which an allowable margin when molding the protruding portions is wide, the protruding portions may be integrally formed as well in the process of molding the cell box 1.

As illustrated in FIG. 1, the side wall portion 2 defining the side surfaces of the housing space 3 includes a pair of first side walls 2a and 2a′ opposed to each other in a first direction H1 and each extending in a second direction H2 orthogonal to the first direction H1, and a pair of second side walls 2b and 2b′ opposed to each other in the second direction H2 and each extending in the first direction H1. The side surfaces of the housing space 3 are defined by inner surfaces 2ai, 2a′i, 2bi, and 2b′i of the pair of first side walls 2a and 2a′ and the pair of second side walls 2b and 2b′ facing the housing space 3, respectively.

In the present embodiment, as illustrated in FIG. 1, four recessed portions con1, con2, con3, and con4 recessed to the side opposite to the housing space 3 are formed on the inner surfaces 2ai and 2a′i of the pair of first side walls 2a and 2a′ among the pair of first side walls 2a and 2a′ and the pair of second side walls 2b and 2b′. When the portions of the inner surfaces 2ai and 2a′i in which the recessed portions con1, con2, con3, and con4 are not formed are referred to as main portions of the inner surfaces 2ai and 2a′i, both ends of the first space PSR in the first direction H1 are defined by the main portions of the inner surfaces 2ai and 2a′i of the pair of first side walls 2a and 2a′. Although a case in which both ends of the first space PSR in the second direction H2 are defined by the main portions of the inner surfaces 2bi and 2b′i of the pair of second side walls 2b and 2b′ will be described as an example, the disclosure is not limited thereto. In the cell box 1, for example, one or more recessed portions recessed to the side opposite to the housing space 3 may be formed on the inner surfaces 2ai, 2a′i, 2bi, and 2b′i of at least one side wall 2a, 2a′, 2b, or 2b′ of the pair of first side walls 2a and 2a′ and the pair of second side walls 2b and 2b′.

Although a case in which each of the above-described four recessed portions con1, con2, con3, and con4 defines one second space, and the four recessed portions con1, con2, con3, and con4 define the above-described four separate second spaces HSR1, HSR2, HSR3, and HSR4 will be described as an example in the present embodiment, the disclosure is not limited thereto. Only some (for example, one) recessed portions of the plurality of recessed portions may define the second spaces, and in this case, as many protruding portions as the number of recessed portions defining the second spaces may be provided in the bottom portion 3bo. That is, the cell box 1 may include a recessed portion defining no second spaces, and the recessed portion defining no second spaces is different from the recessed portions defining the second spaces in that a part of the protective sheet 10 is not disposed and no protruding portion is provided in the recessed portion.

Although a case in which, as illustrated in FIG. 1, four recessed portions con1, con2, con3, and con4 defining the second spaces HSR1, HSR2, HSR3, and HSR4 are formed further on one side of each of the pair of first side walls 2a and 2a′ than the central portion thereof in the second direction H2 and further on the other side of each of the pair of first side walls 2a and 2a′ than the central portion thereof in the second direction H2 is described as an example in the present embodiment, the disclosure is not limited thereto. A recessed portion defining a second space may be formed at the central portion of each of the pair of first side walls 2a and 2a′ in the second direction H2.

As illustrated in FIG. 2, the protective sheet 10 is formed in a shape in which the protective sheet 10 can be housed in the housing space 3 in accordance with the shape of the housing space 3. To be specific, the protective sheet 10 has a shape including four protruding portions that can be disposed in the four second spaces HSR1, HSR2, HSR3, and HSR4. The protective sheet 10 has a shape including a cutout portion at the central portion of each of two end portions of the protective sheet 10 opposed to each other in the first direction H1.

In addition, four holes 10a, 10b, 10c, and 10d are formed in the protective sheet 10 at the four positions respectively overlapping the four protruding portions 4a, 4b, 4c, and 4d when the protective sheet 10 is housed in the housing space 3.

As illustrated in FIGS. 4 and 5, a layered body 30 in which the display panel 20 and the protective sheet 10 alternately overlap is housed in the housing space 3 of the cell box 1. The holes 10a, 10b, 10c, and 10d which are larger than the protruding portions 4a, 4b, 4c, and 4d when viewed from the normal direction of the bottom surface of the housing space 3 are formed at parts of the protective sheet 10, and the protruding portion 4a is inserted into the hole 10a of the protective sheet 10, the protruding portion 4b is inserted into the hole 10b of the protective sheet 10, the protruding portion 4c is inserted into the hole 10c of the protective sheet 10, and the protruding portion 4d is inserted into the hole 10d of the protective sheet 10.

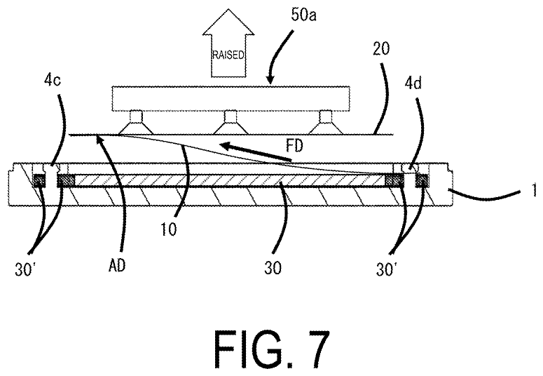

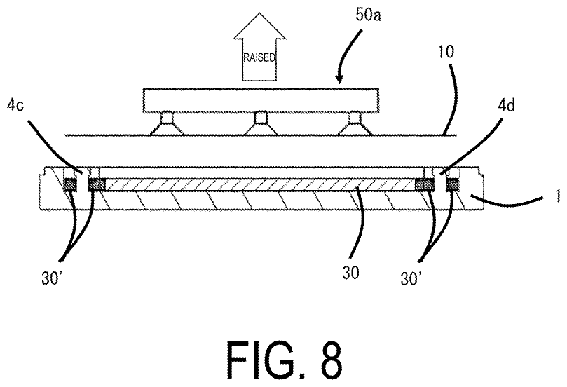

A size of each of the four holes 10a, 10b, 10c, and 10d of the protective sheet 10 is preferably determined in consideration of the control accuracy of a general-purpose display panel removal device 50a (see FIGS. 7 and 8) including a suction portion. For example, each of the four holes 10a, 10b, 10c, and 10d is preferably formed to have an appropriate size in which, when the protective sheet 10 is to be removed by using the general-purpose display panel removal device 50a including a suction portion, the protective sheet 10 is easily removed, but when the display panel 20 is to be removed by using the general-purpose display panel removal device 50a including a suction portion and the protective sheet 10 is lifted up while being stuck to the display panel 20, the protective sheet 10 hits the protruding portions 4a, 4b, 4c, and 4d and falls off.

Based on the relationship between the first space PSR in which the display panel 20 illustrated in FIG. 1 can be disposed and the shape of the protective sheet 10 illustrated in FIG. 2, the protective sheet 10 includes as many overhanging portions more overhanging than the display panel 20 when the layered body 30 in which the display panel 20 and the protective sheet 10 alternately overlap is viewed from the normal direction of the bottom surface as the four protruding portions included in the protective sheet 10 that can be disposed in the four second spaces HSR1, HSR2, HSR3, and HSR4. Thus, as illustrated in FIGS. 4 and 5, in the cell box 1 of the present embodiment, the first space PSR in which the display panel 20 can be disposed is a part of the housing space 3 in which the layered body 30 including the display panel 20 and the protective sheet 10 alternately overlapping is housed, and a size of the first space PSR is smaller than a size of the housing space 3. Note that although the case in which the width of the first space PSR in the first direction H1 is greater than that of the first space PSR in the second direction H2 has been described as an example in the present embodiment, the disclosure is not limited thereto. The width of first space PSR in the second direction H2 may be greater than that of the first space PSR in the first direction H1, the width of the first space PSR in the first direction H1 may be equal to the width of the first space PSR in the second direction H2, and the shape of the first space PSR may be appropriately changed in accordance with the shape of the display panel 20.

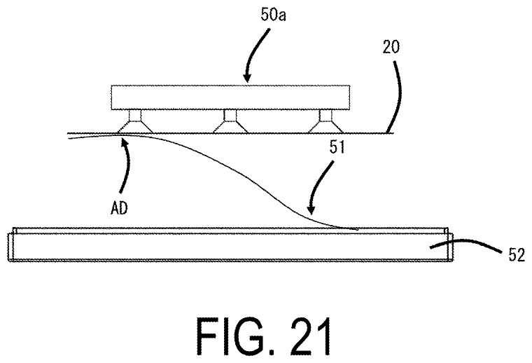

FIG. 21 is a view for explaining a problem that occurs when a display panel 20 is removed from a housing space of a known cell box 52 by using a general-purpose display panel removal device 50a including a suction portion.

As illustrated in FIG. 21, unlike the cell box 1 of the present embodiment, the known cell box 52 includes no protruding portions at the bottom portion defining the bottom surface of the housing space, and a protective sheet 51 housed in the housing space of the known cell box 52 includes no holes at the positions corresponding to the protruding portions.

The display panel 20 and the protective sheet 51 are alternately housed in the housing space of the known cell box 52. When the display panel 20 is removed in the process of alternately sucking and removing the display panel 20 and the protective sheet 51 by using the general-purpose display panel removal device 50a including a suction portion, the protective sheet 51 may stick to a sticking spot AD on the back surface of the display panel 20, and the protective sheet 51 may be lifted up along with the display panel 20. Since such a protective sheet 51 is not sucked by the suction portion of the display panel removal device 50a, there is a problem in that the protective sheet 51 falls into the display panel removal device 50a other than the cell box 52 or at an unpredictable position, and thereby interruption of the display panel removal process or the like may be caused.

FIG. 7 is a diagram illustrating an example of a case in which the display panel 20 is removed from the housing space 3 of the cell box 1 according to the first embodiment by using the general-purpose display panel removal device 50a including a suction portion. FIG. 8 is a diagram illustrating an example of a case in which the protective sheet 10 is removed from the housing space 3 of the cell box 1 according to the first embodiment by using the general-purpose display panel removal device 50a including a suction portion.

As illustrated in FIG. 7, when the display panel 20 is removed from the housing space 3 of the cell box 1 by using the general-purpose display panel removal device 50a including a suction portion, the protective sheet 10 may stick to a sticking spot AD on the back surface of the display panel 20 and the protective sheet 10 may be lifted up along with the display panel 20.

As illustrated in FIG. 6, the cell box 1 includes the first portion 4al extending in the normal direction of the bottom surface of the housing space 3 and the second portion 4a2 more distant from the bottom surface than the first portion 4al is, and the second portion 4a2 includes the protruding portion 4a including the overhanging portion PRP more overhanging than the first portion 4al when viewed from the normal direction of the bottom surface. The cell box 1 includes, for example, the rod-shaped protruding portions 4a, 4b, 4c, and 4d whose distal ends are bulged, and the protective sheet 10 illustrated in FIG. 2 is fitted via the holes 10a, 10b, 10c, and 10d to the corresponding protruding portions 4a, 4b, 4c, and 4d.

As illustrated in FIG. 7, when the display panel 20 is removed from the housing space 3 of the cell box 1 by using the general-purpose display panel removal device 50a including a suction portion, even if the protective sheet 10 disposed between the display panels 20 is stuck to the back surface of the display panel 20 and is lifted up along with the display panel 20, the protective sheet 10 is caught by one or more of the four protruding portions 4a, 4b, 4c, and 4d and falls. That is, when the display panel 20 is sucked and lifted by using the general-purpose display panel removal device 50a including a suction portion, if the protective sheet 10 is stuck at the sticking spot AD on the back surface of the display panel 20, the protective sheet 10 is once pulled in the pulling direction FD, however, if the suction portion is further raised, the protective sheet 10 is caught by one or more of the four protruding portions 4a, 4b, 4c, and 4d, and thus the protective sheet 10 is peeled off from the back surface of the display panel 20 and falls into the cell box 1.

Therefore, according to the cell box 1, the protective sheet 10 can be prevented from being lifted up along with the display panel 20, and the display panel removing process can be prevented from being interrupted due to, for example, the protective sheet 10 falling into the display panel removal device 50a other than the cell box 1 or at an unpredictable position.

Furthermore, according to the cell box 1, since the protruding portions 4a, 4b, 4c, and 4d are not in direct contact with the display panel 20, the shape of the protruding portions 4a, 4b, 4c, and 4d does not need to be a shape in consideration of the removal of the display panel 20, and the disclosure is not limited thereto. For example, each of the protruding portions 4a, 4b, 4c, and 4d may have a shape in which at least the overhanging portions PRP overhang to the side opposite to the first space PSR.

Note that although the case in which the cell box 1 includes the four protruding portions 4a, 4b, 4c, and 4d has been described as an example in the present embodiment, the disclosure is not limited thereto. The above-described effects can be obtained as long as the cell box 1 includes one or more protruding portions, and thus the number of protruding portions can be appropriately determined.

Note that when the protective sheet 10 is removed from the housing space 3 of the cell box 1 by using the general-purpose display panel removal device 50a including a suction portion illustrated in FIG. 8 after the process of removing the display panel 20 from the housing space 3 of the cell box 1 by using the general-purpose display panel removal device 50a including a suction portion illustrated in FIG. 7, the suction portion lifts the protective sheet 10 vertically, and thus the protective sheet 10 is not caught by the protruding portions 4a, 4b, 4c, and 4d.

Although the case in which the components of the cell box 1 other than the protruding portions 4a, 4b, 4c, and 4d are all made of expanded polystyrene (EPS) having the same expansion ratio, and the protruding portions 4a, 4b, 4c, and 4d are made of expanded polystyrene having a lower expansion ratio than the expanded polystyrene used to form the components of the cell box 1 other than the protruding portions 4a, 4b, 4c, and 4d has been described as an example in the present embodiment, the disclosure is not limited thereto. For example, the protruding portions 4a, 4b, 4c, and 4d may be formed of a resin material such as a polyethylene (PE) or a polycarbonate (PC). Note that an expansion ratio of the expanded polystyrene means how much the expanded polystyrene is expanded, and the higher the expansion ratio is, the softer the feel of the molded product is, and the lower the expansion ratio is, the harder the feel of the molded product is.

Note that the process for manufacturing a molded product of expanded polystyrene includes, for example, a process of forming pre-expanded particles at a predetermined expansion ratio and a molding process of charging the pre-expanded particles at the predetermined expansion ratio into a mold to mold the pre-expanded particles in a predetermined shape.

Note that the display panel 20 may be, for example, a liquid crystal display panel or a self-luminous display panel, and a display method thereof is not particularly limited. In addition, the display panel 20 may be a display panel before peripheral circuit components and the like are mounted thereon, or may be a display panel on which peripheral circuit components and the like are mounted. For example, the display panel 20 may be a display panel on which a printed wired board (PWB), which is a printed circuit board including only wiring lines, is mounted, or may be a display panel on which a system on film (SOF), which is a film having installed peripheral circuit components thereon, is mounted.

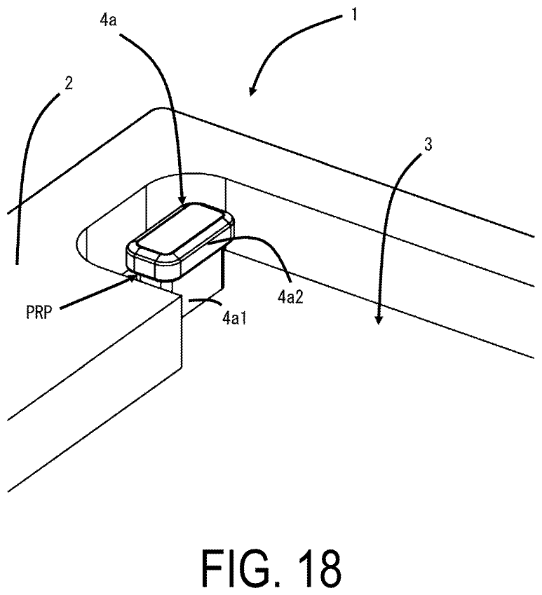

FIG. 18 is a view illustrating another example of the protruding portion that can be provided in the bottom portion 3bo of the housing space 3 of the cell box 1. The shape of the protruding portions 4a, 4b, 4c, and 4d is not limited to a circular shape in a plan view as illustrated in FIG. 6 (each of the first portion and the second portion has a circular shape in a plan view), and may be, for example, a substantially rectangular shape in a plan view as illustrated in FIG. 18 (each of the first portion and the second portion has a substantially rectangular shape in a plan view). Note that, in the example of FIG. 18, the corners of the rectangle are chamfered. The protruding portion illustrated in FIG. 18 also includes a first portion 4al extending in the normal direction of the bottom surface of the housing space 3 and a second portion 4a2 more distant from the bottom surface than the first portion 4al is, and the second portion 4a2 includes an overhanging portion PRP more overhanging than the first portion 4a1 when viewed from the normal direction of the bottom surface.

### Second Embodiment

Next, a second embodiment of the disclosure will be described below. A cell box 1a of the present embodiment is different from the cell box 1 described in the first embodiment in that both ends of the first space PSR in the first direction H1 in which the display panel 20 can be disposed are defined by protruding portions 14a, 14b, 14c, and 14d, and both ends of the first space PSR in the second direction H2 in which the display panel 20 can be disposed are defined by the inner surfaces of a pair of second side walls 12b and 12b′, respectively, facing a housing space 3a. The others are as described in the first embodiment. For convenience of description, members having the same functions as those illustrated in diagrams of the first embodiment are denoted by the same reference signs, and descriptions thereof are omitted.

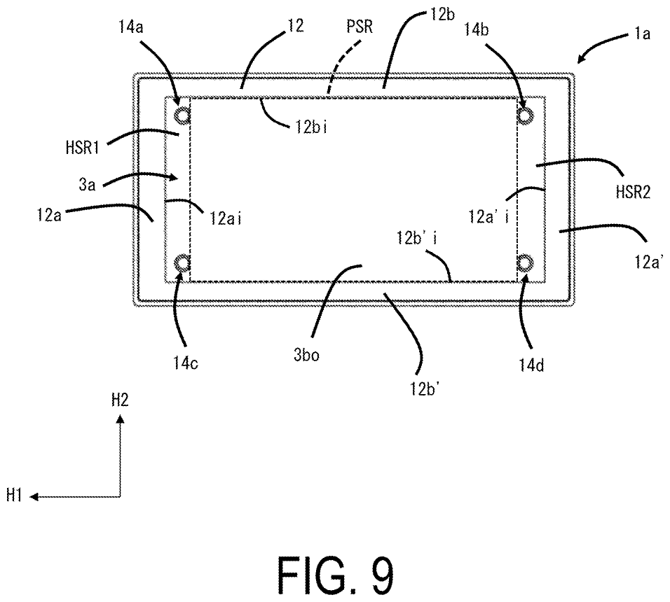

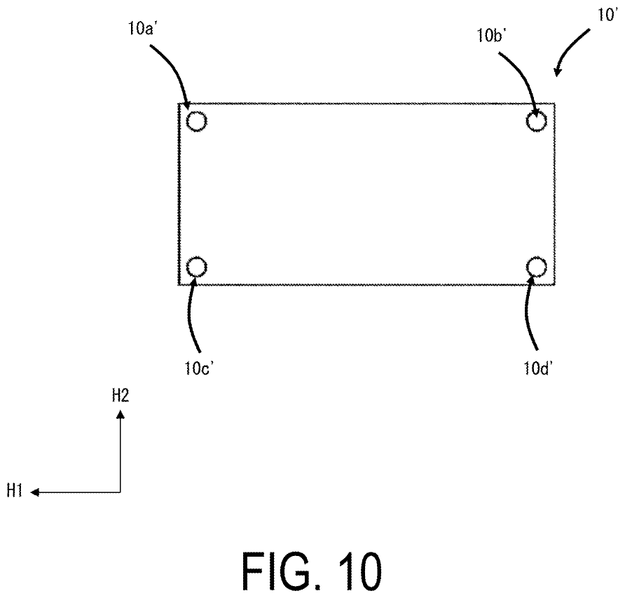

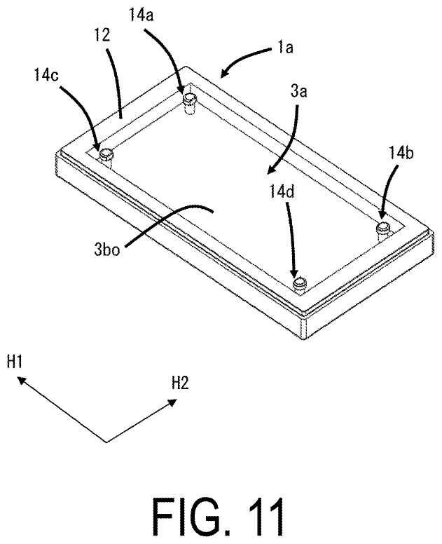

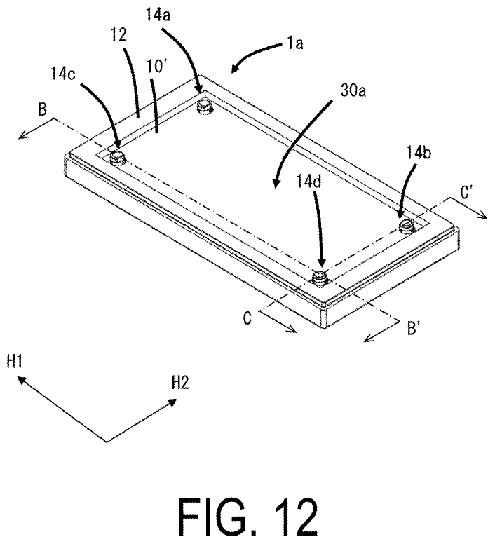

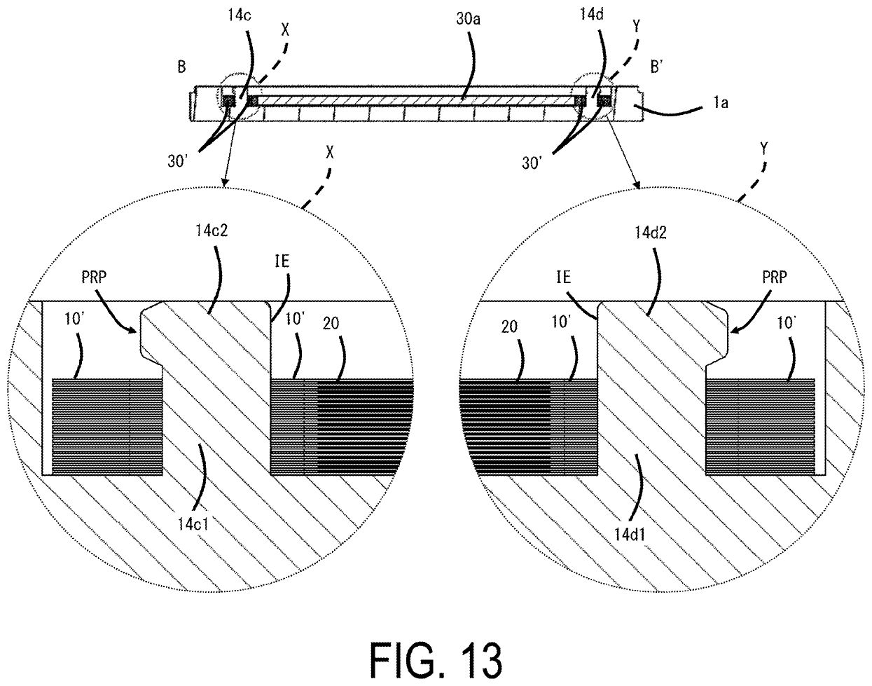

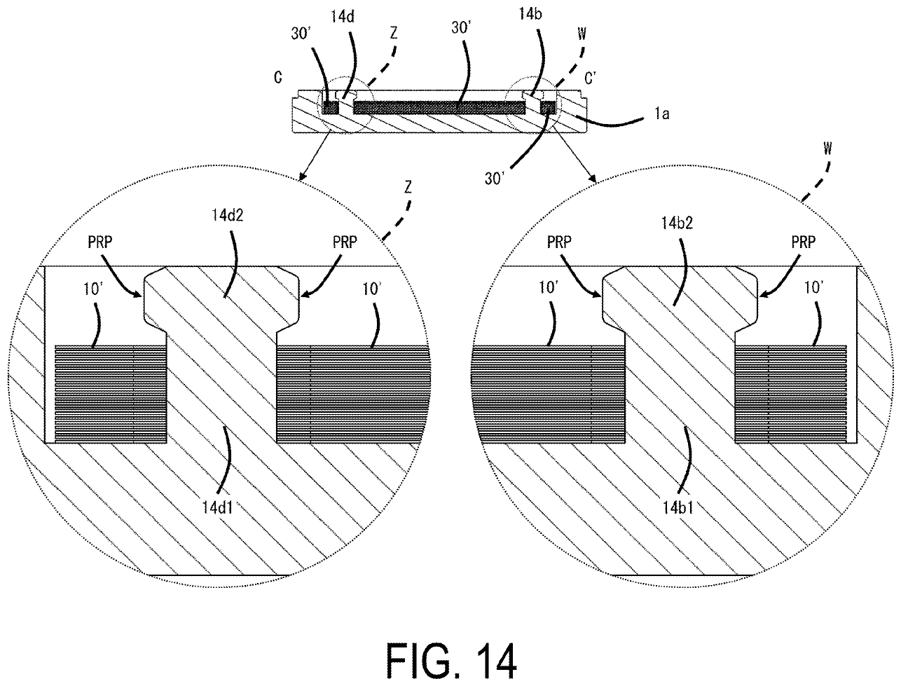

FIG. 9 is a plan view illustrating a schematic configuration of the cell box 1a according to the second embodiment. FIG. 10 is a plan view illustrating an example of a protective sheet 10′ housed in the housing space 3a of the cell box 1a according to the second embodiment. FIG. 11 is a perspective view illustrating a schematic configuration of the cell box 1a according to the second embodiment. FIG. 12 is a perspective view of a state in which the display panel 20 and the protective sheet 10′ are housed in the housing space 3a of the cell box 1a according to the second embodiment. FIG. 13 is a cross-sectional view taken along line B-B′ of FIG. 12, illustrating a state in which the display panel 20 and the protective sheet 10′ are housed in the housing space 3a of the cell box 1a according to the second embodiment. Furthermore, FIG. 13 is a cross-sectional view taken along line B-B′ when viewed from the inside of the housing space 3a toward the inner surface of the second side wall 12b′ as illustrated in FIG. 12. Furthermore, in the partially enlarged view of the X portion and the partially enlarged view of the Y portion illustrated in FIG. 13, hatching of the cut surfaces of the display panel 20 and the protective sheet 10′ is omitted. FIG. 14 is a cross-sectional view taken along line C-C′ of FIG. 12, illustrating a state in which the display panel 20 and the protective sheet 10′ are housed in the housing space 3a of the cell box 1a according to the second embodiment. Furthermore, FIG. 14 is a cross-sectional view taken along line C-C′ when viewed from the inside of the housing space 3a toward the inner surface of a first side wall 12a′ as illustrated in FIG. 12. Furthermore, in the partially enlarged view of the Z portion and the partially enlarged view of the W portion illustrated in FIG. 14, hatching of the cut surfaces of the display panel 20 and the protective sheet 10′ is omitted.

As illustrated in FIGS. 9 and 11, a plurality of protruding portions, for example, four protruding portions 14a, 14b, 14c, and 14d in the present embodiment, are provided in the bottom portion 3bo defining the bottom surface of the housing space 3a of the cell box 1a. In addition, the housing space 3a of the cell box 1a includes a first space PSR in which the display panel 20 can be disposed and two second spaces HSR1 and HSR2 in which the display panel 20 is not disposed and a part of the protective sheet 10′ can be disposed. The second space HSR1 is located at the left side in FIG. 9 which is further on one side than the first space PSR in the first direction H1, and the second space HSR2 is located at the right side in FIG. 9 which is further on the other side than the first space PSR in the first direction H1. In the second space HSR1, the protruding portions 14a and 14c that are some of the four protruding portions 14a, 14b, 14c, and 14d are provided as first protruding portions, and in the second space HSR2, the protruding portions 14b and 14d that are the remainder of the four protruding portions 14a, 14b, 14c, and 14d are provided as second protruding portions. Note that the first protruding portions refer to protruding portions provided in the second space HSR1 among the plurality of protruding portions, and the second protruding portions refer to protruding portions provided in the second space HSR2 among the plurality of protruding portions. In the cell box 1a, both ends of the first space PSR in the first direction H1 are defined by the protruding portions 14a and 14c that are the first protruding portions and the protruding portions 14b and 14d that are the second protruding portions, and both ends of the first space PSR in the second direction H2 are defined by the inner surfaces of the pair of second side walls 12b and 12b′ facing the housing space 3a. Furthermore, as illustrated in FIG. 9, in the cell box 1a, the positions of the protruding portions 14a and 14c that are the first protruding portions defining both ends of the first space PSR in the first direction H1 and the protruding portions 14b and 14d that are the second protruding portions are respectively aligned in the second direction H2. That is, the positions of the protruding portions 14a an 14b in the second direction H2 are aligned, and the positions of the protruding portions 14c and 14d in the second direction H2 are aligned.

Although the case in which the two protruding portions 14a and 14c are provided as the first protruding portions and the two protruding portions 14b and 14d are provided as the second protruding portions has been described above as an example in the present embodiment, the disclosure is not limited thereto. The number of the first protruding portions and the number of the second protruding portions are not particularly limited as long as one or more first protruding portions define one side of both ends of the first space PSR in the first direction H1 and one or more second protruding portions define the other side of both ends of the first space PSR in the first direction H1. For example, the number of the first protruding portions may be different from the number of the second protruding portions. In addition, although the case in which all of the four protruding portions 14a, 14b, 14c, and 14d are protruding portions defining both ends of the first space PSR in the first direction H1 has been described as an example in the present embodiment, the disclosure is not limited thereto. For example, the plurality of protruding portions including the first protruding portions and the second protruding portions may include a protruding portion not defining both ends of the first space PSR in the first direction H1, and the protruding portion not defining both ends of the first space PSR in the first direction H1 may be either the first protruding portion or the second protruding portion. In addition, although the case in which the positions of the protruding portions 14a and 14b in the second direction H2 are aligned and the protruding portions 14c and 14d in the second direction H2 are aligned has been described as an example in the present embodiment, the disclosure is not limited thereto. The positions of all or some of one or more first protruding portions and all or some of one or more second protruding portions in the second direction H2 may not be aligned. Note that the alignment of the positions of the first protruding portions and the second protruding portions in the second direction H2 includes not only a case in which the positions in the second direction H2 completely coincide with each other but also a case in which the first protruding portions and the second protruding portions at least partially overlap each other when viewed from the first direction H1 orthogonal to the second direction H2.

Although, in the cell box 1 of the first embodiment described above, the first space PSR in which the display panel 20 can be disposed is defined by a part of the side wall portion 2 and the display panel 20 can be in contact with only the side wall portion 2, in the cell box 1a of the present embodiment, the first space PSR in which the display panel 20 can be disposed is defined by a part of a side wall portion 12 and the four protruding portions 14a, 14b, 14c, and 14d, and the display panel 20 can be in contact with the side wall portion 12 and the four protruding portions 14a, 14b, 14c, and 14d.

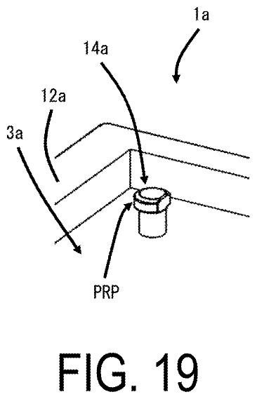

As illustrated in FIG. 11 and FIG. 19 (an enlarged view of the protruding portion 14a), each of the protruding portions 14a, 14b, 14c, and 14d provided in the bottom portion 3bo defining the bottom surface of the housing space 3a includes a first portion extending in the normal direction of the bottom surface of the housing space 3a (i.e., the upper surface of the bottom portion 3bo facing the housing space 3a) and a second portion more distant from the bottom surface than the first portion is, and the second portion includes an overhanging portion more overhanging than the first portion when viewed from the normal direction of the bottom surface. For example, each of the protruding portions 14a, 14b, 14c, and 14d is a rod-shaped protruding portion whose distal end is bulged. As illustrated in the partially enlarged views of the X and Y portions in FIG. 13 and the partially enlarged views of the Z and W portions in FIG. 14, for example, the second portions 14b2, 14c2, and 14d2 include overhanging portions more overhanging than the first portions 14b1, 14cl, and 14d1 when viewed from the normal direction of the bottom surface.

Since the housing space 3a of the cell box 1a has a rectangular shape that is wider in the first direction H1 than in the second direction H2 orthogonal to the first direction H1 in a plan view as illustrated in FIGS. 9 and 11, the protective sheet 10′ can also have a rectangular shape as illustrated in FIG. 10.

Four holes 10a′, 10b′, 10c′, and 10d′ are formed in the protective sheet 10′ at the four positions respectively overlapping the above-described four protruding portions 14a, 14b, 14c, and 14d when the protective sheet 10′ is housed in the housing space 3a.

As illustrated in FIGS. 12, 13, and 14, a layered body 30a in which the display panel 20 and the protective sheet 10′ alternately overlap is housed in the housing space 3a of the cell box 1a. The holes 10a′, 10b′, 10c′, and 10d′ which are larger than the protruding portions 14a, 14b, 14c, and 14d when viewed from the normal direction of the bottom surface of the housing space 3a are formed at parts of the protective sheet 10′. The protruding portion 14a is inserted into the hole 10a′ of the protective sheet 10′, the protruding portion 14b is inserted into the hole 10b′ of the protective sheet 10′, the protruding portion 14c is inserted into the hole 10c′ of the protective sheet 10′, and the protruding portion 14d is inserted into the hole 10d′ of the protective sheet 10′.

A size of each of the four holes 10a′, 10b′, 10c′, and 10d′ is preferably determined in consideration of the control accuracy of a general-purpose display panel removal device 50a (see FIGS. 7 and 8) including a suction portion. For example, each of the four holes 10a′, 10b′, 10c′, and 10d′ is preferably formed to have an appropriate size in which, when the protective sheet 10′ is to be removed by using the general-purpose display panel removal device 50a including a suction portion, the protective sheet 10′ can be easily removed, however when the display panel 20 is to be removed by using the general-purpose display panel removal device 50a including a suction portion and the protective sheet 10′ is lifted up while being stuck to the display panel 20, the protective sheet 10′ hits the protruding portions 14a, 14b, 14c, and 14d and falls off.

Based on the relationship between the first space PSR in which the display panel 20 illustrated in FIG. 9 can be disposed and the shape of the protective sheet 10′ illustrated in FIG. 10, in the cell box 1a of the present embodiment, as illustrated in FIGS. 12, 13 and 14, the first space PSR in which the display panel 20 can be disposed is a part of the housing space 3a in which the layered body 30a including the display panel 20 and the protective sheet 10′ alternately overlapping is housed, and the size of the first space PSR is smaller than the size of the housing space 3a. As illustrated in the partially enlarged views of the X and Y portions in FIG. 13 and the partially enlarged views of the Z and W portions in FIG. 14, a portion of the layered body 30a in which the protective sheets 10′ and the display panels 20 overlap is housed in the first space PSR in which the display panel 20 can be disposed, and a portion of the layered body 30a in which only the protective sheets 10′ (both end portions of the layered body 30a in the first direction H1) overlap is housed in the second spaces HSR1 and HSR2 in which the display panel 20 is not disposed and a part of the protective sheet 10′ can be disposed.

As illustrated in the partially enlarged views of the X and Y portions in FIG. 13 and the enlarged view of the protruding portion 14a in FIG. 19, each of the protruding portions 14c and 14d (the same applies to the protruding portions 14a and 14b) is flat on the first space PSR side when viewed from the second direction H2, and includes an overhanging portion PRP at the second portion 14c2 and 14d2 on the side opposite to the first space PSR. As described above, the overhanging portion of the protruding portion preferably overhangs at least to the side opposite to the first space PSR. In addition, the overhanging portions of the protruding portions defining the ends of the first space PSR (in the present embodiment, the first protruding portions and the second protruding portions defining both ends in the first direction H1) preferably do not overhang to the first space PSR side. This also applies to embodiments to be described below.

As described above, in the cell box 1a, each of the protruding portions 14a, 14b, 14c, and 14d does not overhang to at least the first space PSR side, and thus the display panel 20 can be prevented from being caught by the protruding portions 14a, 14b, 14c, and 14d when the display panel 20 is removed.

Note that, as illustrated in the partially enlarged views of the X and Y portions in FIG. 13, there is a portion where only the protective sheets 10′ are layered in the vicinity of an inner end portion IE of the protruding portion in the first space PSR in which the display panel 20 can be disposed. This portion is a clearance required to ensure the positional accuracy of the device and absorb tolerance at the time of molding the cell box in the process of housing the display panel 20 in the housing space 3a of the cell box 1a by using the general-purpose display panel removal device 50a.

According to the cell box 1a, the protective sheet 10′ can be prevented from being lifted up along with the display panel 20, and the display panel removing process can be prevented from being interrupted due to the protective sheet 10′ falling into the display panel removal device 50a other than the cell box 1a or at an unpredictable position.

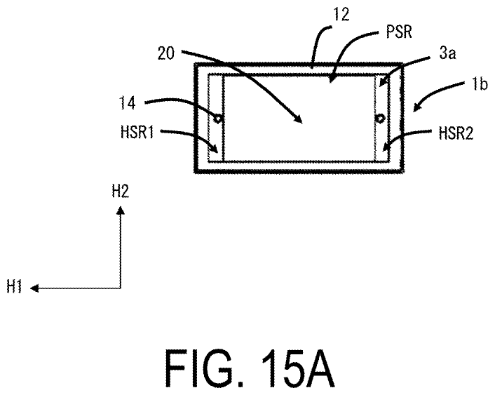

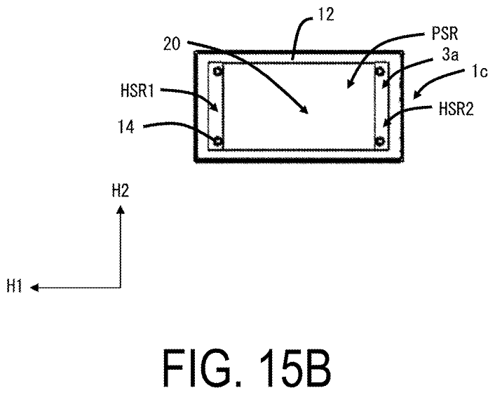

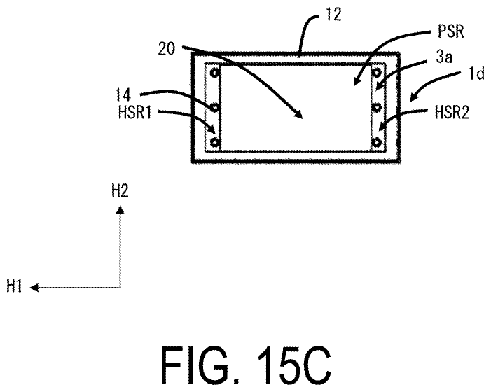

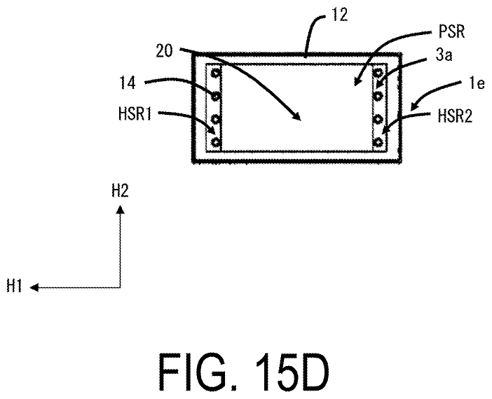

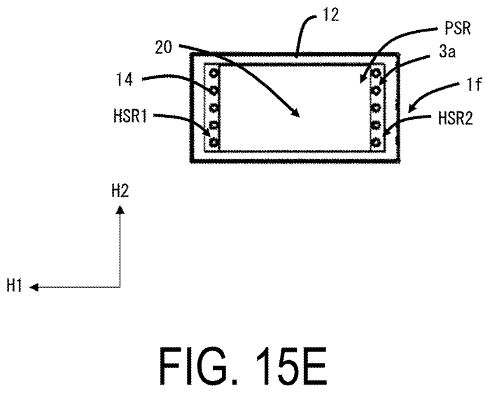

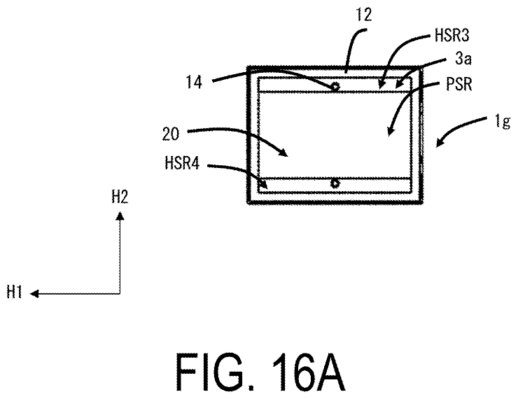

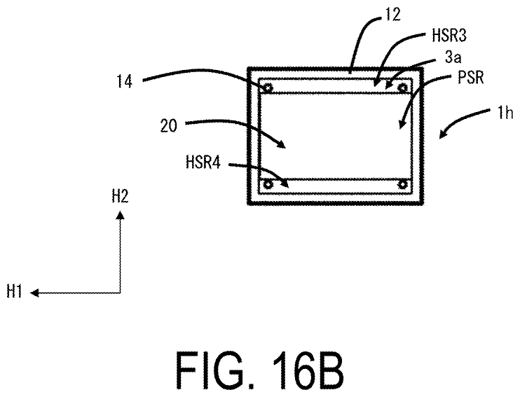

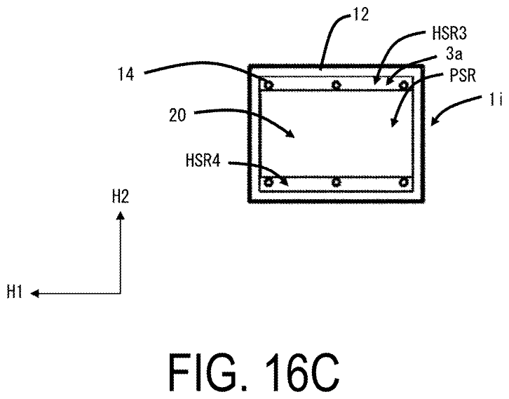

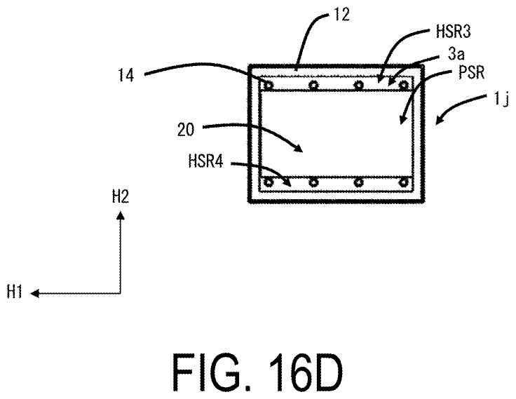

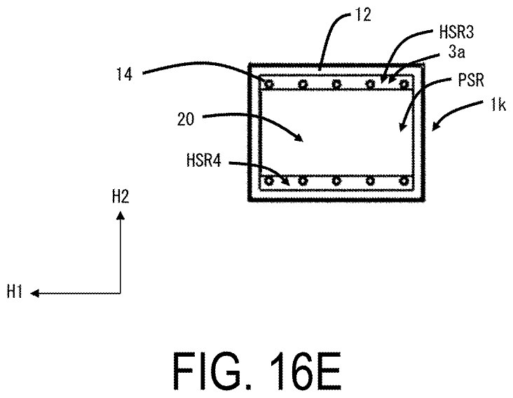

FIGS. 15A to 15E are plan views illustrating schematic configurations of first to fifth modifications of the cell box according to the second embodiment. FIGS. 16A to 16E are plan views illustrating schematic configurations of sixth to tenth modifications of the cell box according to the second embodiment.

As in cell boxes 1b, 1d, and 1f illustrated in FIGS. 15A, 15C, and 15E, the at least one first protruding portion provided in the second space HSR1 defining one side of both ends of the first space PSR in the first direction H1 may include a first protruding portion provided in the central portion of the second space HSR1 in the second direction H2, and the at least one second protruding portion provided in the second space HSR2 defining the other side of both ends of the first space PSR in the first direction H1 may include a second protruding portion provided in the central portion of the second space HSR2 in the second direction H2. Note that the central portion of the second space HSR1 in the second direction H2 means the intermediate position of the second space HSR1 in the second direction H2 and its vicinity, and the central portion of the second space HSR2 in the second direction H2 means the intermediate position of the second space HSR2 in the second direction H2 and its vicinity.

As in the cell boxes 1c, 1d, 1e, and 1f illustrated in FIGS. 15B to 15E, a protruding portion 14 which is at least one first protruding portion defining one side of both ends of the first space PSR in the first direction H1 may include a first protruding portion provided further on one side of the second space HSR1 than the central portion thereof in the second direction H2, and a first protruding portion provided further on the other side of the second space HSR1 than the central portion thereof in the second direction H2, and a protruding portion 14 which is at least one second protruding portion defining the other side of both ends of first space PSR in the first direction H1 may include a second protruding portion provided further on one side of the second space HSR2 than the central portion thereof in the second direction H2, and a second protruding portion provided further on the other side of the second space HSR2 than the central portion thereof in the second direction H2.

The cell box 1b illustrated in FIG. 15A includes one pair of protruding portions 14, the cell box 1c illustrated in FIG. 15B includes two pairs of protruding portions 14, the cell box 1d illustrated in FIG. 15C includes three pairs of protruding portions 14, the cell box 1e illustrated in FIG. 15D includes four pairs of protruding portions 14, and the cell box 1f illustrated in FIG. 15E includes five pairs of protruding portions 14. Note that, in the cell box 1c illustrated in FIG. 15B, each of two pairs of protruding portions 14 is provided at a corresponding one of four corners of the housing space 3a.

As in cell boxes 1g, 1i, and 1k illustrated in FIGS. 16A, 16C, and 16E, the at least one first protruding portion provided in a second space HSR3 defining one side of both ends of the first space PSR in the second direction H2 may include a first protruding portion provided in the central portion of the second space HSR3 in the first direction H1, and the at least one second protruding portion provided in a second space HSR4 defining the other side of both ends of the first space PSR in the second direction H2 may include a second protruding portion provided in the central portion of the second space HSR4 in the first direction H1. Note that the central portion of the second space HSR3 in the first direction H1 means the intermediate position of the second space HSR3 in the first direction H1 and its vicinity, and the central portion of the second space HSR4 in the first direction H1 means the intermediate position of the second space HSR4 in the first direction H1 and its vicinity.

As in the cell boxes 1h, 1i, 1j, and 1k illustrated in FIGS. 16B to 16E, a protruding portion 14 which is at least one first protruding portion defining one side of both ends of the first space PSR in the second direction H2 may include a first protruding portion provided further on one side of the second space HSR3 than the central portion thereof in the first direction H1, and a first protruding portion provided further on the other side of the second space HSR3 than the central portion thereof in the first direction H1, and a protruding portion 14 which is at least one second protruding portion defining the other side of both ends of the first space PSR in the second direction H2 may include a second protruding portion provided further on one side of the second space HSR4 than the central portion thereof in the first direction H1, and a second protruding portion provided further on the other side of the second space HSR4 than the central portion thereof in the first direction H1.

The cell box 1g illustrated in FIG. 16A includes one pair of protruding portions 14, the cell box 1h illustrated in FIG. 16B includes two pairs of protruding portions 14, the cell box 1i illustrated in FIG. 16C includes three pairs of protruding portions 14, the cell box 1j illustrated in FIG. 16D includes four pairs of protruding portions 14, and the cell box 1k illustrated in FIG. 16E includes five pairs of protruding portions 14. Note that, in the cell box 1h illustrated in FIG. 16B, each of two pairs of protruding portions 14 is provided at a corresponding one of four corners of the housing space 3a.

Although the case in which the positions of the pairs of protruding portions 14 in the first direction H1 are respectively aligned in the cell boxes 1g, 1h, 1i, 1j, and 1k illustrated in FIGS. 16A to 16E has been described as an example, the disclosure is not limited thereto. The positions of all or some of one or more first protruding portions and all or some of one or more second protruding portions in the first direction H1 may not be aligned. Note that the alignment of the positions of the first protruding portions and the second protruding portions in the first direction H1 includes not only a case in which the positions in the first direction H1 completely coincide with each other but also a case in which the first protruding portions and the second protruding portions at least partially overlap each other when viewed from the second direction H2 orthogonal to the first direction H1.

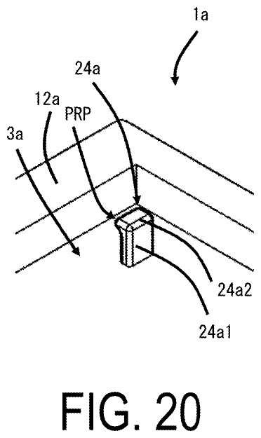

FIG. 20 is a view illustrating another example of a protruding portion that can be provided in the bottom portion 3bo of the housing space 3a of the cell boxes 1a to 1k. A shape of the protruding portions of the cell boxes 1a to 1k is not limited to the shape illustrated in FIG. 19 (that is, a shape obtained by cutting out a part of the second portion having a circular shape in a plan view on the first space PSR side), and may be, for example, an L shape (hook shape) in a side view as illustrated in FIG. 20. In a protruding portion 24a illustrated in FIG. 20, a first portion 24al extending in the normal direction of the bottom surface of the housing space 3a includes a flat portion on the first space PSR side. In addition, a second portion 24a2 which is more distant from the bottom surface of the housing space 3a than the first portion 24al is extends from the first portion 24al to the side opposite to the first space PSR to form an overhanging portion PRP. Also with respect to the protruding portion 24a illustrated in FIG. 20, the display panel 20 can be prevented from being caught by the protruding portion 24a when the display panel 20 is removed. Note that the shapes of the protruding portions illustrated in FIGS. 19 and 20 can also be applied to protruding portions of the third embodiment described below.

### Third Embodiment

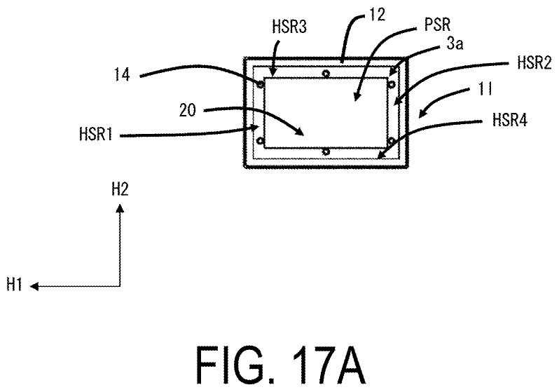

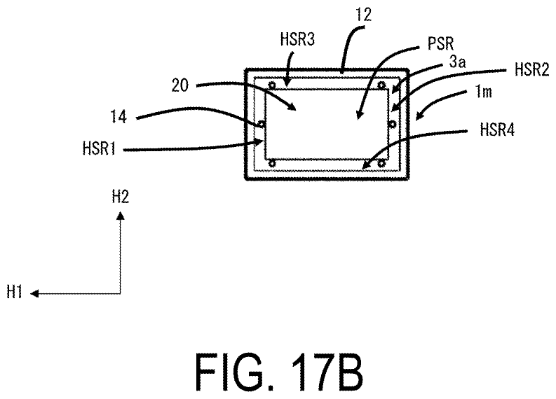

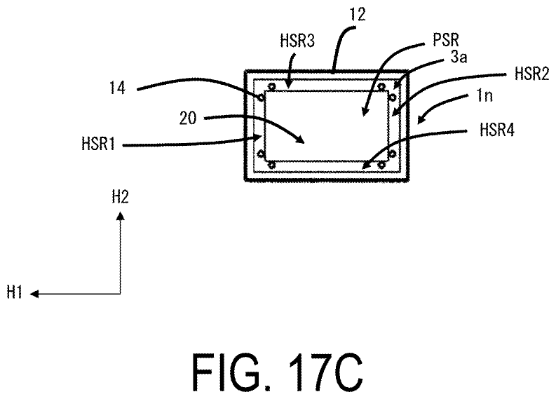

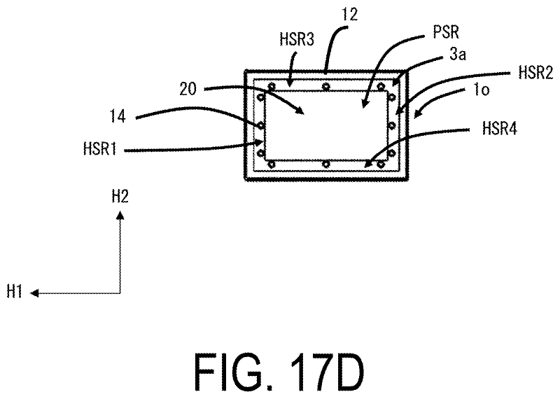

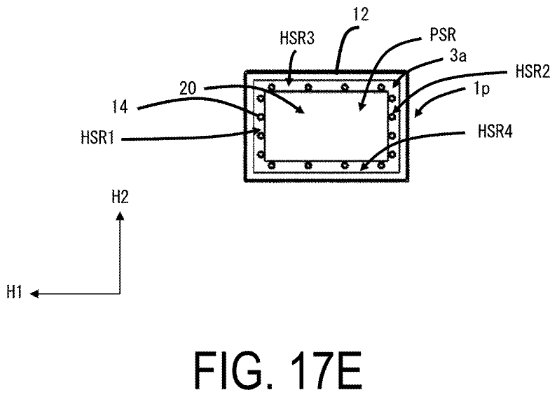

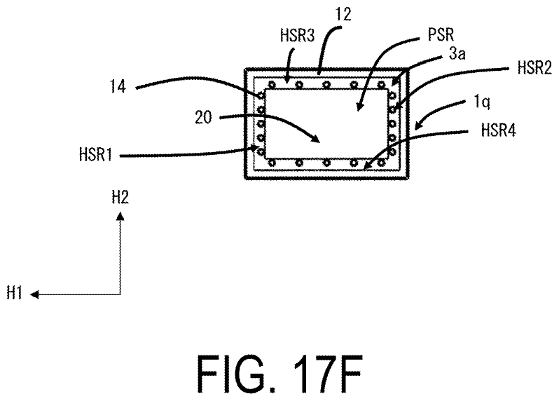

Next, the third embodiment of the disclosure will be described with reference to FIGS. 17A to 17F. The cell boxes 1l, 1m, 1n, 1o, 1p, and 1q according to the present embodiment are different from the cell box described in the second embodiment in that a pair of protruding portions including the first protruding portion and the second protruding portion provided in the first direction H1 described in the second embodiment is combined with a pair of protruding portions including the third protruding portion and the fourth protruding portion provided in the second direction H2 described in the second embodiment. Other configurations are as described in the second embodiment. For convenience of explanation, members having the same functions as those described in diagrams of the second embodiment are denoted by the same reference signs, and descriptions thereof may be omitted.

FIGS. 17A to 17F are plan views illustrating schematic configurations of a cell box according to the third embodiment and first to fifth modifications of the cell box according to the third embodiment.

In the cell boxes 1l, 1m, 1n, 1o, 1p, and 1q illustrated in FIGS. 17A to 17F, a plurality of protruding portions 14 are provided in the bottom portion 3bo defining the bottom surface of the housing space 3a, and the first space PSR is surrounded by the second spaces HSR1, HSR2, HSR3, and HSR4. In a portion further on one side than the first space PSR in the first direction H1 among the second spaces HSR1, HSR2, HSR3, and HSR4, that is, the second space HSR1, one or more first protruding portions which are some of the plurality of protruding portions 14 are provided. In a portion further on the other side than the first space PSR in the first direction H1 among the second spaces HSR1, HSR2, HSR3, and HSR4, that is, the second space HSR2, one or more second protruding portions which are some of the plurality of protruding portions 14 are provided. In a portion further on one side than the first space PSR in the second direction H2 among the second spaces HSR1, HSR2, HSR3, and HSR4, that is, the second space HSR3, one or more third protruding portions which are some of the plurality of protruding portions 14 are provided. In a portion further on the other side than the first space PSR in the second direction H2 among the second spaces HSR1, HSR2, HSR3, and HSR4, that is, the second space HSR4, one or more fourth protruding portions which are the remainder of the plurality of protruding portions 14 are provided. Both ends of the first space PSR in the first direction H1 are defined by at least one first protruding portion of the one or more first protruding portions and at least one second protruding portion of the one or more second protruding portions, and both ends of the first space PSR in the second direction H2 are defined by at least one third protruding portion of the one or more third protruding portions and at least one fourth protruding portion of the one or more fourth protruding portions.

In addition, although the case in which, as in the cell boxes 1l, 1m, 1n, 1o, 1p, and 1q illustrated in FIGS. 17A to 17F, the positions of the first protruding portion and the second protruding portion defining both ends of the first space PSR in the first direction H1 are aligned in the second direction H2 and the positions of the third protruding portion and the fourth protruding portion defining both ends of the first space PSR in the second direction H2 are aligned in the first direction H1 has been described as an example in the present embodiment, the disclosure is not limited thereto. Positions of all or some of the at least one first protruding portion and all or some of the at least one second protruding portion defining both ends of the first space PSR in the first direction H1 may not be aligned in the second direction H2. In addition, positions of all or some of the at least one third protruding portion and all or some of the at least one fourth protruding portion defining both ends of the first space PSR in the second direction H2 may not be aligned in the first direction H1.

In the cell boxes 1m, 1o, and 1q illustrated in FIGS. 17B, 17D, and 17F, the at least one first protruding portion defining one side of both ends of the first space PSR in the first direction H1 includes a first protruding portion provided in the central portion of the second space HSR1 in the second direction H2, and the at least one second protruding portion defining the other side of both ends of the first space PSR in the first direction H1 includes a second protruding portion provided in the central portion of the second space HSR2 in the second direction H2. In addition, the at least one third protruding portion defining one side of both ends of the first space PSR in the second direction H2 includes a third protruding portion provided further on one side of the second space HSR3 than the central portion thereof in the first direction H1 and a third protruding portion provided further on the other side of the second space HSR3 than the central portion thereof in the first direction H1. In addition, the at least one fourth protruding portion defining the other side of both ends of the first space PSR in the second direction H2 includes a fourth protruding portion provided further on one side of the second space HSR4 than the central portion thereof in the first direction H1 and a fourth protruding portion provided further on the other side of the second space HSR4 than the central portion thereof in the first direction H1.

In addition, in the cell boxes 1l illustrated in FIG. 17A, the at least one third protruding portion defining one side of both ends of the first space PSR in the second direction H2 includes a third protruding portion provided in the central portion of the second space HSR3 in the first direction H1, and the at least one fourth protruding portion defining the other side of both ends of the first space PSR in the second direction H2 includes a fourth protruding portion provided in the central portion of the second space HSR4 in the first direction H1. In addition, the at least one first protruding portion defining one side of both ends of the first space PSR in the first direction H1 includes a first protruding portion provided further on one side of the second space HSR1 than the central portion thereof in the second direction H2 and a first protruding portion provided further on the other side of the second space HSR1 than the central portion thereof in the second direction H2. In addition, the at least one second protruding portion defining the other side of both ends of the first space PSR in the first direction H1 includes a second protruding portion provided further on one side of the second space HSR2 than the central portion thereof in the second direction H2 and a second protruding portion provided further on the other side of the second space HSR2 than the central portion thereof in the second direction H2.

In addition, in the cell boxes 1n, 1o, 1p, and 1q illustrated in FIGS. 17C, 17D, 17E, and 17F, the at least one first protruding portion defining one side of both ends of the first space PSR in the first direction H1 includes a first protruding portion provided further on one side of the second space HSR1 than the central portion thereof in the second direction H2 and a first protruding portion provided further on the other side of the second space HSR1 than the central portion thereof in the second direction H2. In addition, the at least one second protruding portion defining the other side of both ends of the first space PSR in the first direction H1 includes a second protruding portion provided further on one side of the second space HSR2 than the central portion thereof in the second direction H2 and a second protruding portion provided further on the other side of the second space HSR2 than the central portion thereof in the second direction H2. In addition, the at least one third protruding portion defining one side of both ends of the first space PSR in the second direction H2 includes a third protruding portion provided further on one side of the second space HSR3 than the central portion thereof in the first direction H1 and a third protruding portion provided further on the other side of the second space HSR3 than the central portion thereof in the first direction H1. In addition, the at least one fourth protruding portion defining the other side of both ends of the first space PSR in the second direction H2 includes a fourth protruding portion provided further on one side of the second space HSR4 than the central portion thereof in the first direction H1 and a fourth protruding portion provided further on the other side of the second space HSR4 than the central portion thereof in the first direction H1.

In addition, as in the cell boxes 1l, 1m, 1n, 1o, 1p, and 1q illustrated in FIGS. 17A to 17F, overhanging portions PRP of the at least one first protruding portion defining one side of both ends of the first space PSR in the first direction H1, the at least one second protruding portion defining the other side of both ends of the first space PSR in the first direction H1, the at least one third protruding portion defining one side of both ends of the first space PSR in the second direction H2, and the at least one fourth protruding portion defining the other side of both ends of the first space PSR in the second direction H2 preferably do not overhang to the first space PSR side. According to such cell boxes 1l, 1m, 1n, 1o, 1p, and 1q, the display panel 20 can be prevented from being caught by the protruding portions when the display panel 20 is removed.

The cell boxes 1l and 1m illustrated in FIGS. 17A and 17B include three pairs of protruding portions 14, the cell box 1n illustrated in FIG. 17C includes four pairs of protruding portions 14, the cell box 1o illustrated in FIG. 17D includes six pairs of protruding portions 14, the cell box 1p illustrated in FIG. 17E includes eight pairs of protruding portions 14, and the cell box 1q illustrated in FIG. 17F includes ten pairs of protruding portions 14.

According to the cell boxes 1l, 1m, 1n, 1o, 1p, and 1q, the protective sheet 10′ can be prevented from being lifted up along with the display panel 20, and the display panel removing process can be prevented from being interrupted due to the protective sheet 10′ falling into the display panel removal device 50a other than the cell boxes 1l, 1m, 1n, 1o, 1p, and 1q, or at an unpredictable position.

### APPENDIX

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A cell box comprising:
a bottom portion defining a bottom surface of a housing space in which a display panel and a protective sheet are housed in an overlapping manner; and
a side wall portion defining a side surface of the housing space,
wherein the housing space includes a first space in which the display panel is disposed and a second space in which the display panel is not disposed and a part of the protective sheet is disposed,
one or more protruding portions protruding into the second space are provided in the bottom portion,
the one or more protruding portions each include a first portion extending in a normal direction of the bottom surface and a second portion more distant from the bottom surface than the first portion is, and
the second portion includes an overhanging portion more overhanging than the first portion when viewed from the normal direction of the bottom surface.

2. The cell box according to claim 1,
wherein the side wall portion includes a pair of first side walls opposed to each other in a first direction and each extending in a second direction orthogonal to the first direction, and a pair of second side walls opposed to each other in the second direction and each extending in the first direction, and
the side surface of the housing space is defined by an inner surface of each of the pair of first side walls and the pair of second side walls facing the housing space.

3. The cell box according to claim 2,
wherein one or more recessed portions recessed to a side opposite to the housing space are formed on the inner surface of at least one side wall of the pair of first side walls and the pair of second side walls, and
when a portion of the inner surface in which none of the one or more recessed portions is formed is referred to as a main portion of the inner surface,
both ends of the first space in the first direction are defined by the main portions of the inner surfaces of the pair of first side walls, and
both ends of the first space in the second direction are defined by the main portions of the inner surfaces of the pair of second side walls.

4. The cell box according to claim 3,
wherein the housing space includes one or more of the second spaces defined by each of one or more specific recessed portions among the one or more recessed portions, and
the one or more protruding portions protruding toward each of the one or more second spaces are provided in the bottom portion.

5. The cell box according to claim 4,
wherein a specific recessed portion among the one or more specific recessed portions is formed in a central portion of each of the pair of first side walls in the second direction.

6. The cell box according to claim 4,
wherein a specific recessed portion among the one or more specific recessed portions is formed further on one side of each of the pair of first side walls than a central portion of each of the pair of first side walls in the second direction and further on the other side of each of the pair of first side walls than the central portion of each of the pair of first side walls in the second direction.

7. The cell box according to claim 2,
wherein a plurality of the protruding portions are provided in the bottom portion,
the housing space includes two of the second spaces,
one of the two second spaces is located further on one side than the first space in the first direction,
the other of the two second spaces is located further on the other side than the first space in the first direction,
one or more first protruding portions which are some of the plurality of protruding portions are provided in one of the two second spaces,
one or more second protruding portions which are a remainder of the plurality of protruding portions are provided in the other of the two second spaces,
both ends of the first space in the first direction are defined by at least one first protruding portion of the one or more first protruding portions and at least one second protruding portion of the one or more second protruding portions, and
both ends of the first space in the second direction are defined by the inner surfaces of the pair of second side walls.

8. The cell box according to claim 7,
wherein positions of the at least one first protruding portion and the at least one second protruding portion are aligned in the second direction.

9. The cell box according to claim 7,
wherein the at least one first protruding portion includes a first protruding portion provided in a central portion of the second space in the second direction, and
the at least one second protruding portion includes a second protruding portion provided in a central portion of the second space in the second direction.

10. The cell box according to claim 7,
wherein the at least one first protruding portion includes a first protruding portion provided further on one side of the second space than a central portion of the second space in the second direction and a first protruding portion provided further on the other side of the second space than the central portion of the second space in the second direction, and
the at least one second protruding portion includes a second protruding portion provided further on one side of the second space than a central portion of the second space in the second direction and a second protruding portion provided further on the other side of the second space than the central portion of the second space in the second direction.

11. The cell box according to claim 2,
wherein a plurality of the protruding portions are provided in the bottom portion,
the first space is surrounded by the second space,
one or more first protruding portions which are some of the plurality of protruding portions are provided in a portion of the second space further on one side than the first space in the first direction,
one or more second protruding portions which are another part of the plurality of protruding portions are provided in a portion of the second space further on the other side than the first space in the first direction,
one or more third protruding portions which are another part of the plurality of protruding portions are provided in a portion of the second space further on one side than the first space in the second direction,
one or more fourth protruding portions which are a remainder of the plurality of protruding portions are provided in a portion of the second space further on the other side than the first space in the second direction,
both ends of the first space in the first direction are defined by at least one first protruding portion of the one or more first protruding portions and at least one second protruding portion of the one or more second protruding portions, and
both ends of the first space in the second direction are defined by at least one third protruding portion of the one or more third protruding portions and at least one fourth protruding portion of the one or more fourth protruding portions.

12. The cell box according to claim 11,
wherein positions of the at least one first protruding portion and the at least one second protruding portion are aligned in the second direction, and
positions of the at least one third protruding portion and the at least one fourth protruding portion are aligned in the first direction.

13. The cell box according to claim 11,
wherein the at least one first protruding portion includes a first protruding portion provided in a central portion of the second space in the second direction,
the at least one second protruding portion includes a second protruding portion provided in a central portion of the second space in the second direction,
the at least one third protruding portion includes a third protruding portion provided further on one side of the second space than a central portion of the second space in the first direction and a third protruding portion provided further on the other side of the second space than the central portion of the second space in the first direction, and
the at least one fourth protruding portion includes a fourth protruding portion provided further on one side of the second space than a central portion of the second space in the first direction and a fourth protruding portion provided further on the other side of the second space than the central portion of the second space in the first direction.

14. The cell box according to claim 11,
wherein the at least one first protruding portion includes a first protruding portion provided further on one side of the second space than a central portion of the second space in the second direction and a first protruding portion provided further on the other side of the second space than the central portion of the second space in the second direction,
the at least one second protruding portion includes a second protruding portion provided further on one side of the second space than a central portion of the second space in the second direction and a second protruding portion provided further on the other side of the second space than the central portion of the second space in the second direction,
the at least one third protruding portion includes a third protruding portion provided further on one side of the second space than a central portion of the second space in the first direction and a third protruding portion provided further on the other side of the second space than the central portion of the second space in the first direction, and
the at least one fourth protruding portion includes a fourth protruding portion provided further on one side of the second space than a central portion of the second space in the first direction and a fourth protruding portion provided further on the other side of the second space than the central portion of the second space in the first direction.

15. The cell box according to claim 1,
wherein the overhanging portion overhangs at least on a side opposite to the first space.

16. The cell box according to claim 7,
wherein the overhanging portion of each of the at least one first protruding portion and the at least one second protruding portion does not overhang toward the first space.

17. The cell box according to claim 11,
wherein the overhanging portion of each of the at least one first protruding portion, the at least one second protruding portion, the at least one third protruding portion, and the at least one fourth protruding portion does not overhang toward the first space.

18. The cell box according to claim 1,
wherein the display panel and the protective sheet are alternately housed in an overlapping manner in the housing space,
the part of the protective sheet is formed with a hole larger than a corresponding one of the one or more protruding portion when viewed from the normal direction of the bottom surface, and
the corresponding one of the one or more protruding portion is inserted into the hole of the protective sheet.
